(19) United States
(12) Patent Application Publication
(10) Pub. No.: US 2018/0297831 A1
(43) Pub. Date: Oct. 18, 2018

(54) BEVERAGE DISPENSING METHOD USING SENSOR ASSEMBLY FOR SENSING DISPENSING OF BEVERAGE

(71) Applicant: Automatic Bar Controls, Inc., Vacaville, CA (US)

(72) Inventors: Thomas R. Hecht, Winters, CA (US); Richard A. Martindale, Vacaville, CA (US)

(21) Appl. No.: 16/014,704

(22) Filed: Jun. 21, 2018

Related U.S. Application Data
(62) Division of application No. 14/841,397, filed on Aug. 31, 2015, now abandoned.
(60) Provisional application No. 62/044,144, filed on Aug. 29, 2014.

(51) Int. Cl. B67D 1/00; H03K 17/972

(52) U.S. Cl. CPC B67D 1/0086; B67D 2210/00091; H03K 17/972

(57) ABSTRACT

A beverage dispensing method for dispensing and sensing the dispensing of one or more beverage components from a bar gun. The method of detecting includes using a sensor associated with a button on the bar gun to detect that the button is depressed to mechanically actuate a valve within a body of the bar gun.

### CROSS-REFERENCES TO RELATED APPLICATIONS

The present application is a divisional application of U.S. application Ser. No. 14/841,397, entitled “BEVERAGE DISPENSING APPARATUS WITH SENSOR ASSEMBLY FOR SENSING DISPENSING OF BEVERAGE,” filed Aug. 31, 2015, which claims priority from U.S. Provisional Application No. 62/044,144, entitled “BEVERAGE DISPENSING APPARATUS WITH SENSOR ASSEMBLY FOR SENSING DISPENSING OF BEVERAGE,” filed on Aug. 29, 2014, the entire contents of which are herein incorporated by reference.

### BACKGROUND

The invention relates to a sensor configuration for a beverage dispensing system for sensing the dispensing of the beverage component. Particularly, the invention relates to a sensor configuration that can be installed on a tower beverage dispensing system or a hand-held beverage dispenser, also known as a bar gun, to sense when a button on the bar gun or tower is depressed, which causes a beverage component to be dispensed, and thus, the sensor configuration can sense the dispensing of a beverage.

Beverage dispensing systems are commonly used in a wide variety of locales, including restaurants, snack bars, convenience stores, movie theaters, and any business where beverages are served. These beverage dispensing systems often dispense a variety of beverages of differing types and flavors, such as flavored carbonated sodas, iced tea, water, or even alcoholic beverages. These devices dispense the variety of beverages either by dispensing a single component beverage or by utilizing a dispensing array, also referred to as a diffuser, through which a single beverage may pass or a base beverage and a beverage additive, flow to a dispense point that facilitates discharge of beverages or beverage additives. The beverage components are then dispensed through a dispensing nozzle into a beverage container.

Some beverage dispensing systems are in the form of a beverage tower while others use a hand-held beverage dispensing handle, commonly referred to as a bar gun. The bar gun uses a single nozzle for dispensing multiple different beverages depending on the needs of the end user. A tower system can have a single nozzle or multiple nozzles for dispensing a beverage. When a single nozzle tower is used, it can be configured to dispense a variety of different beverages using valves in connection with a manifold and system of fluid lines connected to beverage sources for distributing a mixed or single component beverage through a nozzle. Buttons can be used to activate the valves to control the flow of the beverage from the system. The same concept is used with bar guns except that the buttons and valves are located in the bar gun itself rather than in the beverage tower dispenser. Beverage dispensers utilizing this concept have at least one button, and often numerous buttons, for controlling the dispensing of a single beverage component or a mixed beverage into a container.

Because the button valve configuration of conventional bar guns and towers are mechanically, i.e. manually, operated, these dispensing devices often don't have means to monitor the dispensing of beverages from the bar gun or tower, which may be useful for things such as reconciling data with purchase receipts, adjusting inventory and/or monitoring re-order levels, among other things.

Accordingly, it is desirable to develop an assembly that can easily be installed on a bar gun or tower beverage dispensing device such that the depressing of a button and/or dispensing of a beverage component can be sensed.

### BRIEF SUMMARY OF THE INVENTION

The present invention is related to beverage dispensing apparatus that utilizes a sensor assembly to detect when a dispensing button is depressed and thus a beverage component is dispensed.

One embodiment is related to a beverage dispensing apparatus for dispensing one or more beverage components where the beverage dispensing apparatus has a body and at least one button protruding out through the body, the at least one button being adapted to dispense a beverage from the beverage dispensing apparatus. The beverage dispensing apparatus also has at least one sensing element attached to the at least one button and at least one sensor attached to the body and aligned with the at least one sensing element such that when the at least one button is depressed into the body to dispense a beverage, the at least one sensor interacts with the at least one sensing element to sense that the at least one button is depressed. In one embodiment the sensing element is a magnetic element and the sensor senses the movement of the magnetic element.

In some aspects, the at least one button has a shaft and a cap mounted to the top of the shaft and the at least one magnet is attached to the shaft. The shaft can have a bore and the at least one magnet is installed in the bore. In some aspects, the sensor is attached to the body by way of a sensor plate. In some embodiments the sensor plate can have multiple sensors for aligning with multiple respective magnets attached to multiple respective buttons for sensing dispensing of multiple beverage components. The beverage dispensing apparatus can further comprise a cover attached to the body and having apertures allowing the shafts to protrude through the cover with the cover being installed between the sensor plate and the button caps.

Many embodiments in accordance with the present invitation are related to a bar gun for dispensing multiple beverage components, where the bar gun has an elongated body, a plurality of buttons protruding out through the body with the plurality of buttons adapted to dispense one or more of the multiple a beverage components, a plurality of magnet respectively attached to each of the plurality of buttons, and a plurality of sensor attached to the body and each aligned with each respective magnet such that when a buttons is depressed to dispense one or more beverage components, the sensor corresponding with the magnet of the depressed button interacts with the magnet of the depressed button to sense that the button is depressed and a beverage is dispensed.

In some aspects, the bar gun is configured such that multiple buttons can be depressed simultaneously and the respective magnets and sensors for the multiple depressed buttons sense the dispensing of multiple beverage components. In some embodiments, the buttons each have a shaft and a respective cap mounted to the top of the shaft and the respective magnet is attached to the shaft. Each shaft can have a bore with the respective magnet is installed in the bore. In some aspects, the multiple sensors are attached to the body by way of a sensor plate connecting all the sensors together. Some embodiments include a cover attached to the body and having apertures allowing the shafts to protrude through the cover with the cover being installed between the sensor plate and the button caps.

Many embodiments in accordance with the present invention include a method for sensing the dispensing of a beverage from a bar gun that includes depressing one or more of a plurality of buttons protruding through an elongated body of the bar gun, the plurality of buttons adapted to dispense one or more of the multiple a beverage components and the plurality of buttons each having a magnet aligned with respective sensors attached to the body, and sensing the dispensing one or more beverage components when the sensor corresponding with the magnet of the depressed button interacts with the magnet of the depressed button to sense that the button is depressed and a beverage is dispensed.

Further understanding of the nature and the advantages of the embodiments disclosed and suggested herein may be realized by reference to the remaining portions of the specification and the attached drawings.

### BRIEF DESCRIPTION OF THE DRAWINGS

FIG. 1 illustrates a conventional bar gun handle beverage dispensing apparatus.

FIG. 2 illustrates a partially exploded assembly perspective view of a bar gun, in accordance with many embodiments of the present invention.

FIG. 3 illustrates the bar gun of FIG. 2 further including a cover.

FIG. 4 shows a top view of the bar gun of FIG. 2.

FIG. 5 shows a side view of the bar gun of FIG. 2 with one of the buttons in the depressed state.

FIG. 6 illustrates an assembled perspective view of the bar gun of FIG. 2 with one of the buttons in a depressed state.

FIG. 7 illustrates an assembled perspective view of the bar gun of FIG. 3 with one of the buttons in a depressed state.

FIG. 8 illustrates a partially exploded perspective view of a bar gun, in accordance with many embodiments of the present invention.

### DETAILED DESCRIPTION OF THE INVENTION

Embodiments of the invention are generally directed to beverage dispenser sensor assembly for sensing when a beverage dispenser button is depressed and dispensing a beverage component.

In one embodiment of the beverage dispenser in accordance with the present invention magnets and sensors can be installed as part of the original beverage dispensing tower, or hand held beverage dispenser, or as an assembly that can be installed on a pre-existing bar gun or tower beverage dispenser as a retro fit kit. In a circumstance such as upgrading with a retrofit kit, the sensing element and sensor assembly, described herein, can be added to an existing beverage dispensing tower or handle using the existing screw positions of the beverage dispenser.

Hand held beverage dispensers, which allow an operator to dispense a number of different beverages by merely pressing an appropriate button on the dispenser, have been around for many years. One exemplary bar gun is as described in Assignee's pioneering patent, U.S. Pat. No. 4,986,449 to Valiyee, the entirety of which is incorporated herein by reference. An exemplary tower is described in Assignee's patent application, U.S. Patent Application Publication No. US2011/0315711 A1 to Hecht. Other similar bar guns and towers are commercially available from Automatic Bar Controls at www.wunderbar.com.

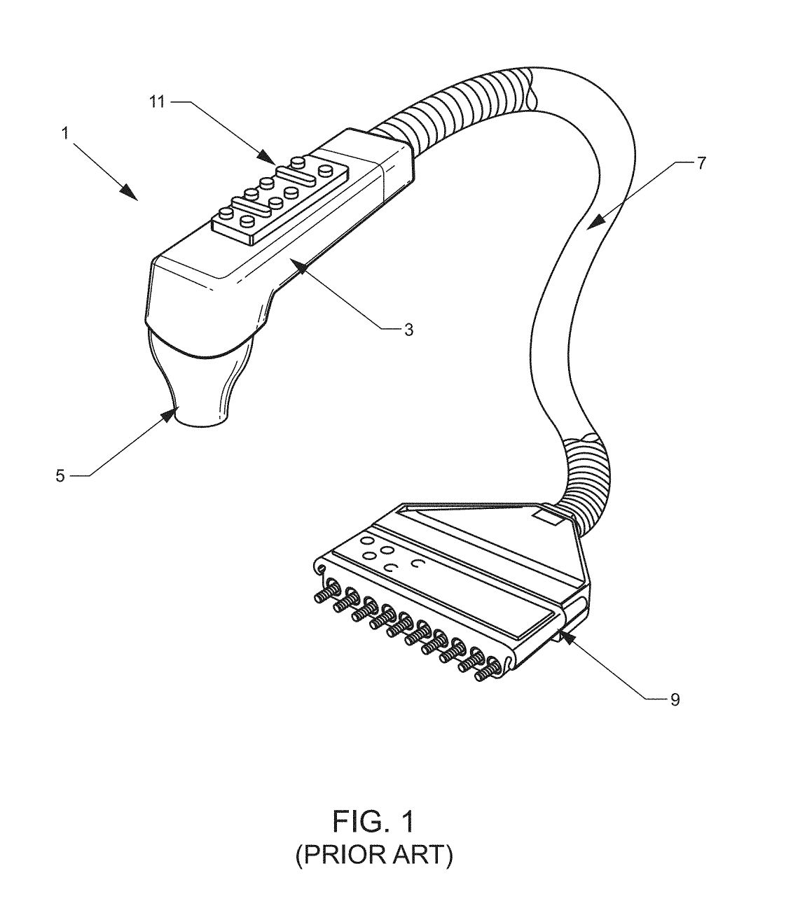

Regarding a bar gun, as seen in Valiyee and illustrated in FIG. 1, the bar gun 1 has a handle 3 that has a nozzle 5 at one end for dispensing the beverage. At the other end, the handle 3 is connected to a flexible line 7 that connects to a brixing device 9 that contains shut off and flow valves for controlling the flow of beverage components to the bar gun. The brixing device 9 is in turn connected to a beverage source (not shown). The bar gun, also has buttons 11 on the handle 3 that activate valves for dispensing a single beverage component or a mixed beverage solution depending on the button 11 pushed by the operator and the configuration of the bar gun 1. Beverage dispensing towers can be configured similarly with a nozzle, a tower, dispensing and flow control valves and buttons for dispensing the beverage, except the buttons are installed on the fixed tower assembly rather than on the handle of a hand held bar gun.

The buttons on a bar gun handle or a tower beverage dispenser allow an operator to select particular beverage components and/or dispense the beverage components in predetermined or customizable flow rates and volumes. These buttons can be numerous, or merely be a single button, depending on the intend use of the operator or establishment utilizing the bar gun or tower. In use, the sensor configuration according to the present invention can be installed on a tower beverage dispensing device or a bar gun, which is connected to a beverage dispensing system, such as the one described above.

Embodiments in accordance with the present invention provide a mechanism for sensing and monitoring the dispensing of a beverage or beverage component from a beverage dispenser like a bar gun. In one embodiment, sensing occurs when a magnet installed in the bar gun button is located within a particular distance of a sensor on a sensor plate. The sensor and magnet can be controlled to send a signal to an “intelligence” system that can record the transaction, adjust inventory, monitor inventory levels, and analyze other data necessary for the venue in which such equipment is installed. Such a system for example receives data indication of a pour, as detected by the sensing elements, and can for example analyze the data of the pour for determining precision pours, tracking the number or amount of pours and tie that information to sales and transactions monitoring, calculating inventory levels based on number and volumes of pours, among other things. One such system, Skyflo®, is commercially available from Automatic Bar Controls Inc. at www.wunderbar.com.

The support circuitry of the sensor may be simply directly wired to a suitable monitoring circuit, or may be completely self-contained with the ability to transmit activation data to a system for monitoring the activity of a venue such as a bar or restaurant such as Skyflo®.

Some Embodiments in accordance with the present invention are related to magnetic sensors, such as Hall-Effect or reed sensors, among others, which positionally detect corresponding magnets coupled to the individual buttons of the bar gun. The type of sensor, cooperating magnet and relative positions between the sensor and magnet are configured so that detection of the button activation i.e. travel, can be accurately sensed and determined to be “inactive” (not dispensing) or “active” (dispensing a beverage) even with a rather small change in the position of the magnet being monitored by the sensors. Depending upon the location and number of sensors employed, either the basic “beverage dispense” of a bar gun can be detected, or the specific Brand/type (Cola, Orange, lemonade, etc.) available to be dispensed by the bar gun. Other types of sensing of the dispensing of the flow are possible with various kinds of sensing methods including, the sensing of the position of the sensing element and buttons, as described here, as well as optically sensing the button movement or even optically, electrically and/or magnetically sensing the flow of beverage component itself through the bar gun fluid channels, among others.

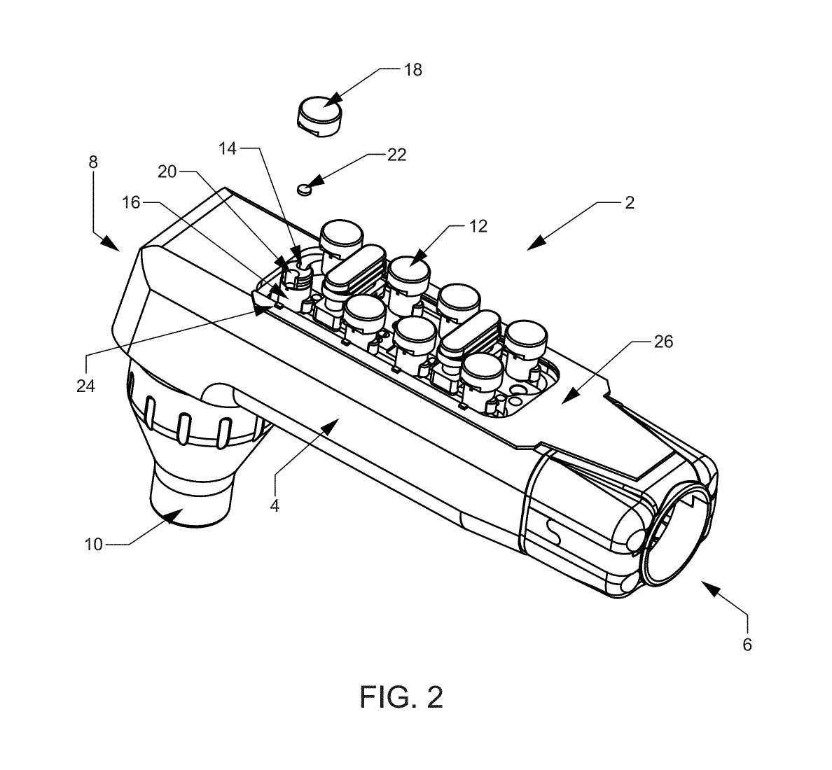

The above aspects of the invention can be further understood with reference to the exemplary devices shown in FIGS. 2-7, although the invention is not limited to the depicted embodiments and may include many variations in accordance with the principles and aspects described herein.

FIG. 2 shows a partially exploded assembly view of a bar gun with a sensor configuration in accordance with the present invention. The bar gun 2 has a body 4 that extends from a back end 6 to a front end 8. Under the front end 8, a nozzle 10 extends from the body 4 for dispensing a beverage component into a suitable container (not shown). On the top side of the body 4 ten buttons 12 protrude up through the body 4, and are connected with valves (not shown) inside the body 4, which work in connection with the brixing device described above in the convention bar gun for dispensing a beverage component when the button 12 is depressed. Ten buttons are shown here, but as few as one button can be used. Alternatively, as many buttons as what is desired by a user that can be utilized on a bar gun 2 may be used.

The buttons 12 have a shaft 14 that rests in a retainer 16 and a cap 18 that rests on top of the shaft 14. When the cap 18 is pressed by a user, the shaft 14 is pressed down within the retainer 16 to activate one of the bar gun valves. The shaft has two bores 20 where a magnet 22 or the sensing element can be installed. A single bore 20 can also be used for installing the magnet 22. The bores 20 are shown on outer and inner sides of the shaft 14, but the bore 20 can be anywhere in the shaft 14 when the magnet 22 is held near a corresponding sensor 24. Here the sensor 24 is shown on a sensor plate 26 the holds multiple sensors 24. The magnet 22 rests in the bore 20 which extends down the shaft 14 to below the retainer 16. When the button 12 is depressed, the magnet rests in the bore and is partially retained by the retainer.

The plate 26 is installed to the top of the bar gun and has two arms that mount the sensors 24 under magnets 22 for each button 12. The sensors 24 can be installed to a sensor plate 26, as shown, or they can independently be installed near a corresponding magnet 22. The sensors 24 are also shown as being aligned with magnets 22 on the outer portions of the buttons 24 near the sides of the bar gun 2, but the sensors can also be installed at inner portions of the buttons 12 near the center line of the body 4 of the bar gun 2.

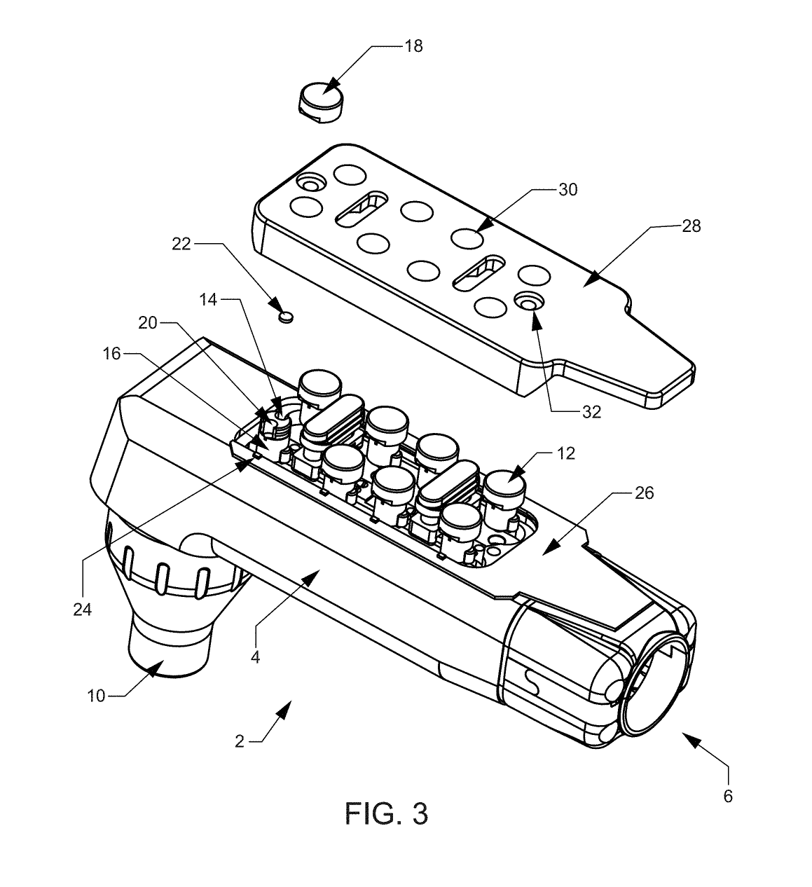

As shown in FIG. 3, a cover 28 that has button apertures 30 and mounting holes 32, can be installed over the button shafts 14 and mounted to the body 4 via the mounting holes 32. The cover 28 protects dirt, liquids and other contaminants from getting in the area of the shaft 14 and retainer 16 as well as the sensors 24.

In operation, when an operator depresses or activates a button 12, they depress the button into the body 4, which activates a valve (not shown) to dispense a beverage. When the button is depressed, the magnet 22 is brought within a closer distance to the sensor 24. The sensor senses the magnet 22, in turn sensing that the button has been depressed, and therefore sensing a beverage component is being dispensed. The signal from the sensing element is in the form of a 4-20 mA current and is transmitted to a current measuring device. The current measuring device may be part of the direct support circuitry of the sensor or part of the self-contained unit with the ability to transmit data to a system, such as Skyflo®. Other configurations for measuring, collecting and transmitting the current information are also possible.

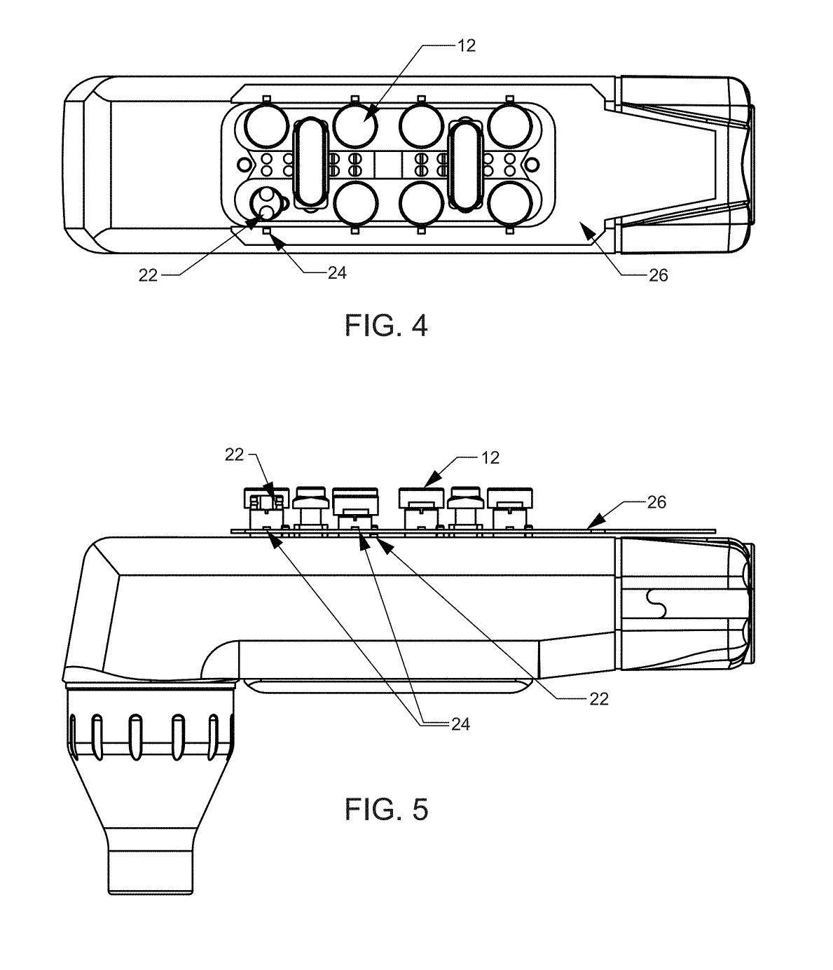

FIG. 4 shows a top view of bar gun 2 with the buttons 12 and the magnet 22 installed in the bore 20 of shaft 14. One of the button caps 18 is shown removed to illustrate the magnet 22 is aligned, to the side, with the sensor 24. FIG. 5 illustrates a side view of the bar gun of FIG. 4 with the magnet 22 and the sensor aligned vertically in the same lateral plane in this view in the button 12 labeled B1. An additional button 12, labeled B2, is shown depressed and the travel of the button can be seen as well as the distance between the magnet 22 and sensor 24 in a depressed and non-depressed or inactive and active state, respectively.

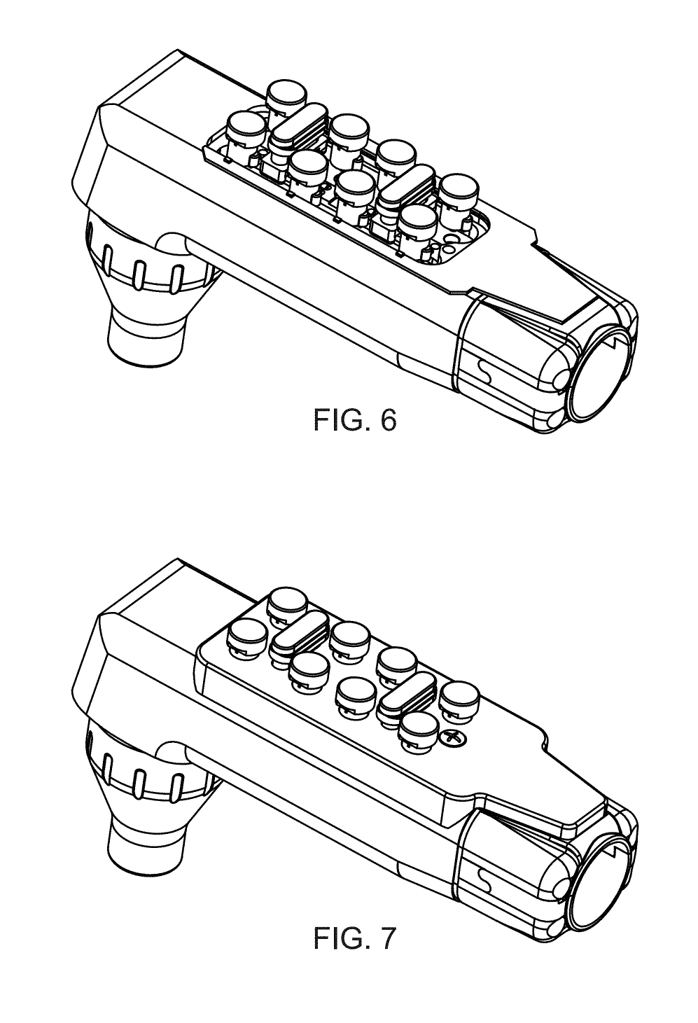

FIG. 6 and FIG. 7 are rendered illustrations of FIG. 2 and FIG. 3 with the magnet and sensor assembly of a bar gun and showing a depressed button with FIG. 6, showing the cover 28 removed, and FIG. 7, showing the cover installed on the bar gun over the sensors 24 and sensor plate 26.

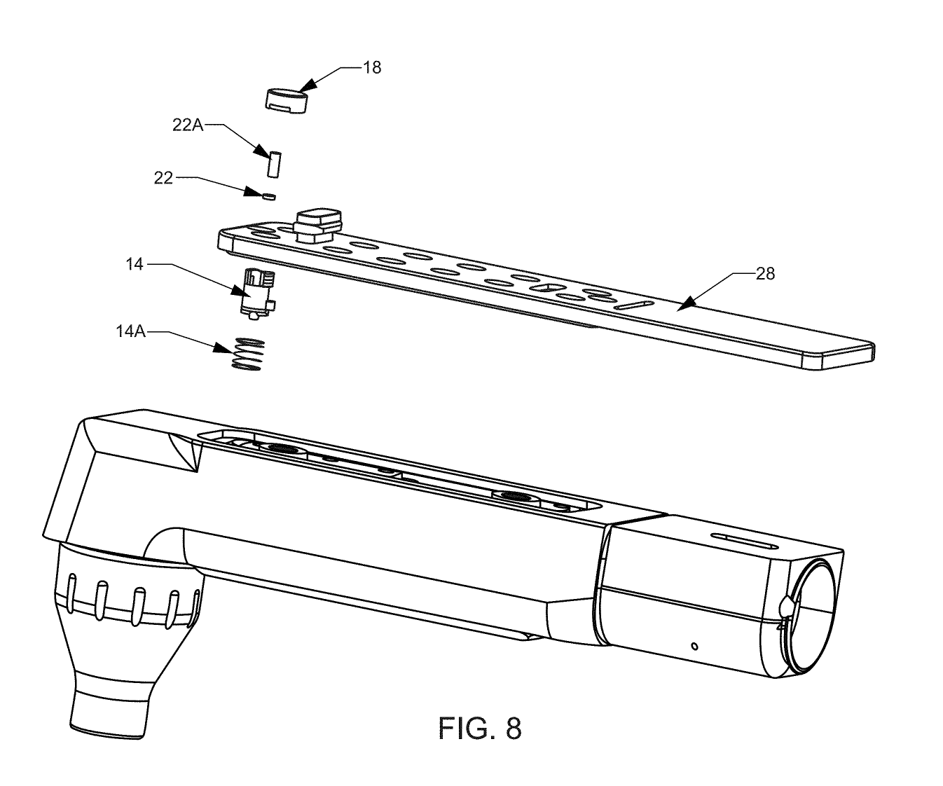

FIG. 8 shows an alternative construction as what is depicted at FIG. 3. Here, an additional spacer 22A, which can be constructed from an elastomeric material such as rubber, can optionally be positioned between the magnet 22 and button cap 18. The spacer 22A helps maintain the magnet 22 in correct position, primarily in the event of shock due to abuse of accidental dropping of the bargun. An additional spring 14A can be optionally positioned below the shaft 14. The spring 14A helps maintain proper travel of the magnet 22 for reliable sensing. The spring 14A also helps counter fictional resistance to the button, which can be caused by dirt, debris or dried (sticky) liquids that can gather over time. Although depicted in tandem, it should be understood that use of the spacer 22A is not reliant on use of the spring 14A, and vice versa.

The above description is illustrative and is not restrictive. A recitation of “a”, “an” or “the” is intended to mean “one or more” unless specifically indicated to the contrary. Many variations of the disclosure will become apparent to those skilled in the art upon review of the disclosure. One or more features from any embodiment described herein may be combined with one or more features of any other embodiment without departing from the scope of the disclosure. The scope of the disclosure should, therefore, be determined not with reference to the above description, but instead should be determined with reference to the pending claims along with their full scope or equivalents.

What is claimed is:

1. A method of detecting one or more beverage components being dispensed from a bar gun, the method comprising:
detecting with a first sensor associated with a button on the bar gun that the button is depressed, wherein depressing the button mechanically actuates a valve within a body of the bar gun, and wherein detecting that the button is depressed indicates that the valve is mechanically actuated by the button to dispense the one or more beverage components.

2. The method of claim 1, wherein the button is coupled to a first sensing element and the first sensor is coupled to the body of the bar gun, and wherein detecting that the button is depressed comprises detecting that the first sensing element is positioned at a first location relative to the first sensor indicating that the button is not mechanically actuating the valve and subsequently detecting with the first sensor that the first sensing element is positioned at a second location relative to the first sensor indicating that the first button is mechanically actuating the valve to dispense the one or more beverage components.

3. The method claim 2, wherein the sensing element is a magnet.

4. The method of claim 3, wherein the magnet is positioned within a bore of a shaft of the button.

5. The method of claim 1, wherein detecting that the button is depressed further comprises detecting a number of times that the one or more beverage components are dispensed.

6. The method of claim 1, wherein detecting that the button is depressed further comprises estimating an amount of the one or more beverage components that are dispensed.

7. The method of claim 1, further comprising:
detecting with a second sensor associated with a second button on the bar gun that the second button is depressed, wherein depressing the second button mechanically actuates a second valve within the body of the bar gun, and wherein detecting that the second button is depressed indicates that the second valve is mechanically actuated by the second button to dispense the one or more beverage components.

8. The method of claim 7, wherein detecting that the button and second button are each depressed is performed simultaneously indicating that the valve and the second valve are simultaneously actuated to dispense the one or more beverage components.
